(19) United States
(12) Patent Application Publication
(10) Pub. No.: US 2008/0272430 A1
(43) Pub. Date: Nov. 6, 2008

(54) SEMICONDUCTOR DEVICE AND METHOD OF FORMING THE SAME

(75) Inventors: Ki-Jae Hur, Seoul (KR); Jun-Hee Lim, Seoul (KR); Hyuck-Chai Jung, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/111,120

(22) Filed: Apr. 28, 2008

(30) Foreign Application Priority Data
Apr. 27, 2007 (KR) 2007-41425

(51) Int. Cl. H01L 29/78

(52) U.S. Cl. 257/330; 257/E29.262

(57) ABSTRACT

A semiconductor device includes an active region defined in a substrate, the active region having a trench extending below a surface of the substrate; an impurity region provided along a bottom surface and a lower sidewall of the trench, wherein an upper portion of the impurity region is spaced apart from the surface of the substrate and an upper portion of the trench; a gate insulating layer provided along an inner surface of the trench; and a gate electrode provided in the trench.

### CROSS-REFERENCE TO RELATED APPLICATIONS

This U.S. non-provisional patent application claims priority under 35 U.S.C § 119 to Korean Patent Application 2007-41425 filed on Apr. 27, 2007, the entirety of which is hereby incorporated by reference.

### BACKGROUND

1. Field of Invention

Embodiments of the present invention relate generally to semiconductor devices and methods of forming the same. More specifically, embodiments of the present invention are directed to a recess channel array transistor and a method of forming the same.

2. Description of the Related Art

Certain characteristics of planar transistors deteriorate when a gate width is reduced to 100 nm or less. As a result of such deterioration, short channel effect such as subthreshold swing, drain induced barrier lowering (DIBL), and increase of junction leakage current can be disadvantageously generated.

A recess channel array transistor may extend an effective channel length to overcome disadvantages such as short channel effect that a planar transistor encounters. However, the threshold voltage of a recess channel array transistor is difficult to control. For example, when an ion implanting process is performed to control a threshold voltage, ions may be implanted into a region below a trench used as a channel, as well as into the surface of the substrate. Ions that are implanted into the surface of the substrate tend to undesirably intensify electric fields and deteriorate refresh characteristics of the recess channel array transistor.

### SUMMARY

Exemplary embodiments of the present invention are directed to methods of fabricating a semiconductor device.

One embodiment exemplarily described herein can be generally characterized as a semiconductor device that includes an active region defined in a substrate, wherein the active region has a trench extending below a surface of the substrate; an impurity region provided along a bottom surface and a lower sidewall of the trench, wherein an upper portion of the impurity region is spaced apart from the surface of the substrate and an upper portion of the trench; a gate insulating layer provided along an inner surface of the trench; and a gate electrode provided in the trench.

### BRIEF DESCRIPTION OF THE DRAWINGS

FIG. 1 is a cross-sectional view illustrating a semiconductor device according to an embodiment of the present invention;

FIG. 2 is a cross-sectional view illustrating a semiconductor device according to another embodiment of the present invention;

FIGS. 3A through 3C are cross-sectional views illustrating a method of forming a semiconductor device according to an embodiment of the present invention;

FIGS. 4A through 4D are cross-sectional views illustrating a method of forming a semiconductor device according to another embodiment of the present invention; and

FIGS. 5A and 5B are cross-sectional views illustrating a method of forming a semiconductor device according to yet another embodiment of the present invention.

### DETAILED DESCRIPTION

Exemplary embodiments of the present invention will now be described more fully hereinafter with reference to the accompanying drawings. These embodiments, however, may be realized in many different forms and should not be construed as limited to the description explicitly set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

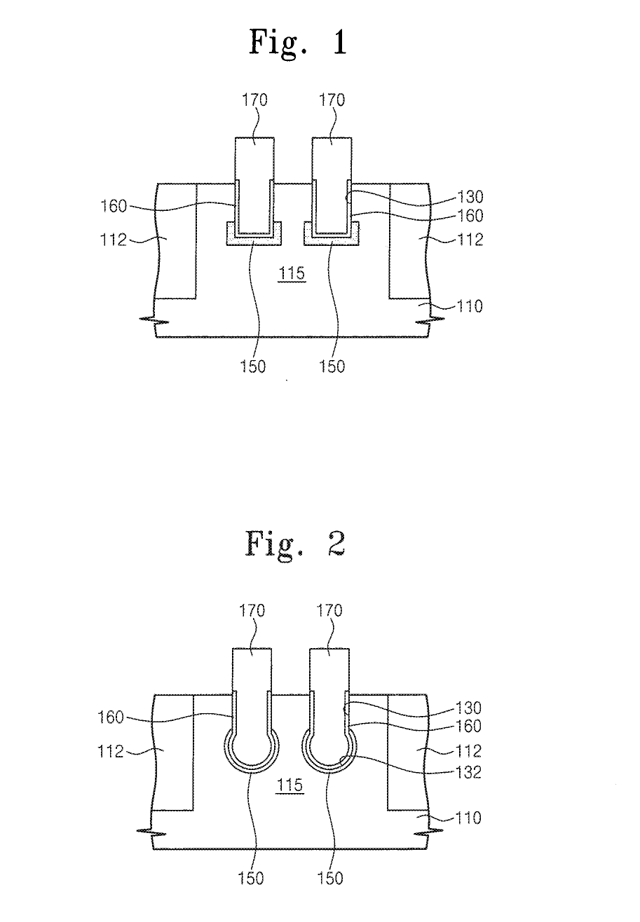

FIG. 1 is a cross-sectional view illustrating a semiconductor device according to an embodiment of the present invention.

Referring to FIG. 1, a semiconductor device according to an embodiment of the present invention may include a semiconductor substrate 110 and a field isolation layer 112 disposed in the semiconductor substrate 110 to define an active region 115.

A trench 130 is disposed in the active region 115. A gate insulating layer 160 is disposed along the inner surface of the trench 130. A gate electrode 170 is disposed on the gate insulating layer 160 to fill the trench 130. Source/drain regions (not shown) are disposed in the active region 115 at both sides of the gate electrode 170. Thus, the gate electrode 170 and the source/drain regions constitute a “recess channel array transistor” (RCAT).

An impurity region 150 is disposed along a lower profile of the gate electrode 170. As exemplarily illustrated, the impurity region 150 may have a substantially U-shaped cross-section and a substantially uniform doping profile. In one embodiment, the impurity region 150 may contain boron ions.

FIG. 2 is a cross-sectional view illustrating a semiconductor device according to another embodiment of the present invention. Concepts described above with respect to the embodiment shown in FIG. 1 that are also present in the embodiment shown in FIG. 2 will not be described in great detail.

A trench 130 is disposed in an active region 115 and a recess region 132 is disposed below the trench 130. The recess region 132 may have a substantially circular cross-section. In one embodiment, the recess region 132 may also have a larger width than that of the trench 130. A gate insulating layer 160 is disposed along the inner surface of the trench 130 and the recess region 132. A gate electrode 170 is disposed on the gate insulating layer 160 to fill the trench 130 and the recess region 132. The gate electrode 170 and source/drain regions (not shown) at both sides of the gate electrode 170 constitute a “recess channel array transistor” (RCAT).

An impurity region 150 is disposed along a lower profile of the gate electrode 170 disposed at the recess region 132. The impurity region 150 may have a substantially circular section and a substantially uniform doping profile. In addition, the impurity region 150 may contain boron ions.

According to embodiments exemplarily described above with respect to FIGS. 1 and 2, a threshold voltage of a recess channel array transistor may be controlled by controlling the type and concentration of impurities within the impurity region 150. Moreover, a thermal diffusion process described below for controlling the threshold voltage may be used to prevent ions from being undesirably introduced into the surface of the active region 115. As a result, junction leakage current may decrease and operation characteristics such as a refresh characteristic of a recess channel array transistor may be enhanced.

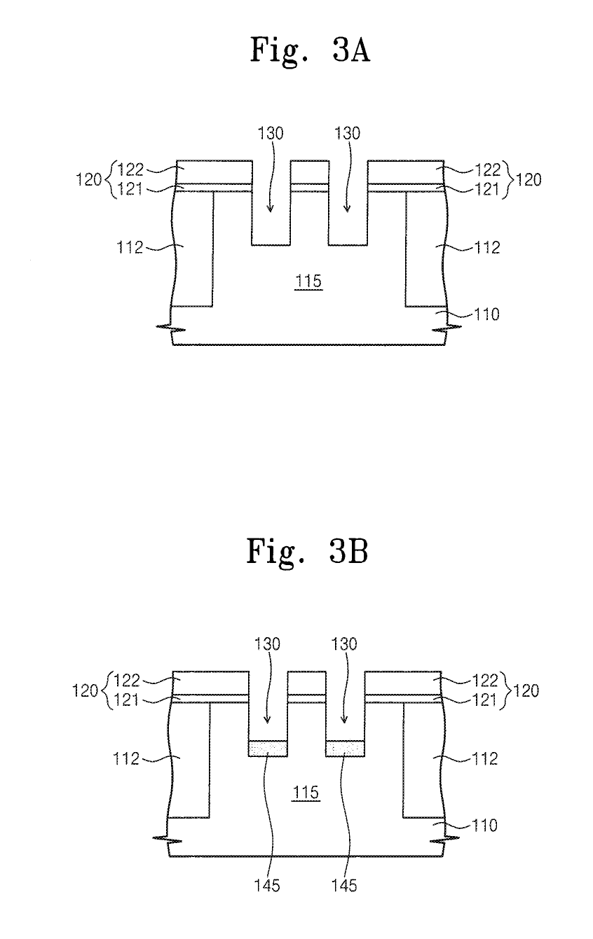

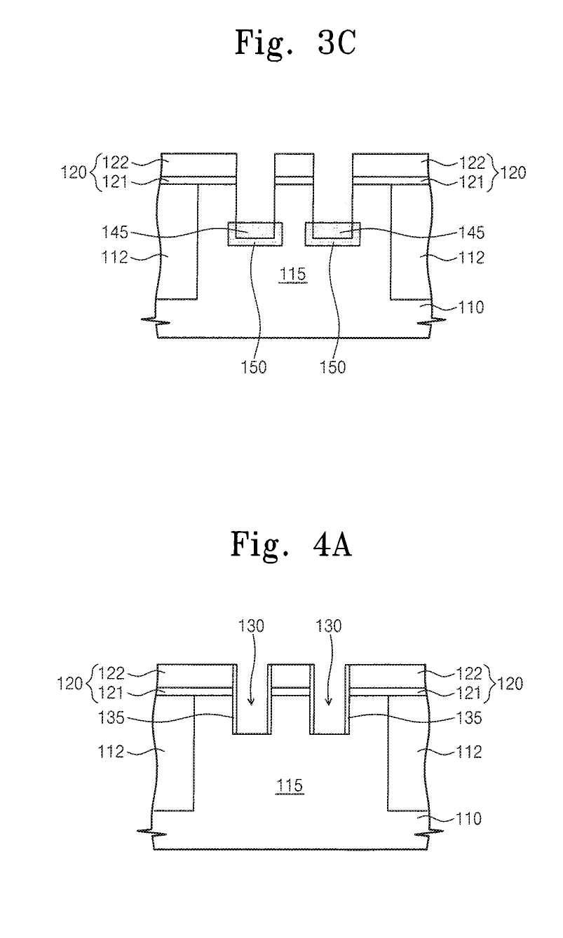

A method of forming a semiconductor device according to an embodiment of the present invention will now be described with reference to FIGS. 3A through 3C.

Referring to FIG. 3A, a field isolation layer 112 is formed on a semiconductor substrate 110 to define an active region 115. A mask pattern 120 is formed on the substrate 110 to define a portion of the active region 115. In one embodiment, the mask pattern 121 may include an oxide pattern 121 and a nitride pattern 122. The oxide pattern 121 may alleviate a stress which may occur between the substrate 110 and the nitride pattern 122. The oxide pattern 121 may, for example, include a material such as a middle-temperature oxide and the nitride pattern 122 may, for example, a material such as silicon oxynitride (SiON).

The substrate 110 is etched using the mask pattern 120 as an etch mask to form a trench 130 in the active region 115.

Referring to FIG. 3B, a material pattern 145 containing impurity ions is formed in a lower portion of the trench 130. In one embodiment, the material pattern 145 may be formed by forming a material layer containing impurity ions on the substrate 110, followed by etching the material layer. In one embodiment, the impurity ions contained the material layer (and, therefore, the material pattern 145) may include boron ions. In one embodiment, the material layer (and, therefore, the material pattern 145) may include a material such as borosilicate glass (BSG). In one embodiment, the material layer may be etched in an etchback process.

Referring to FIG. 3C, an annealing process is performed to form an impurity region 150 in portions of the substrate 110 that are adjacent to and contact the material pattern 145. The impurity region 150 may be formed by diffusing impurity ions (e.g., boron ions) from the material pattern 145 into the substrate 110 during the annealing process. The impurity ions may be substantially uniformly diffused by the annealing process, allowing the impurity region 150 to be substantially uniformly formed along the profile of the material pattern 145. As a result, the impurity region 150 may have, for example, a substantially U-shaped cross-section and a substantially uniform doping profile.

Returning to FIG. 1, the material pattern 145 and the mask pattern 120 are removed using, for example, a wet etch process. An insulating layer and a conductive layer may then be formed along the inner surface of the trench 130 and patterned to form a gate insulating layer 160 and a gate electrode 170, respectively. In one embodiment, the insulating layer may include an oxide formed using, for example, a thermal oxidation process. In one embodiment, the conductive layer may include polysilicon, metal, silicide, or the like or a combination thereof.

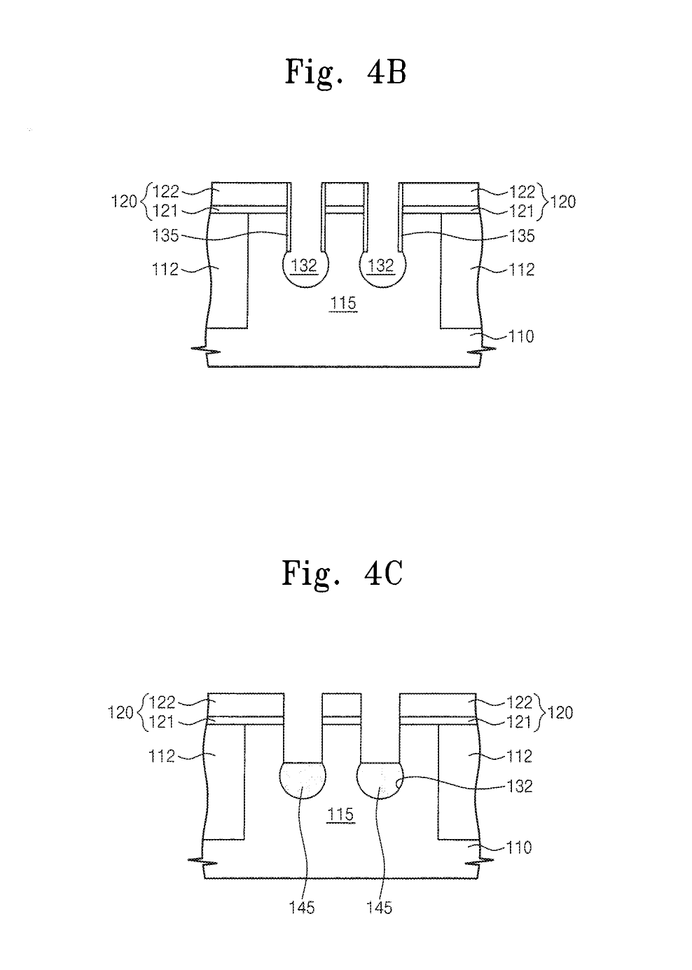

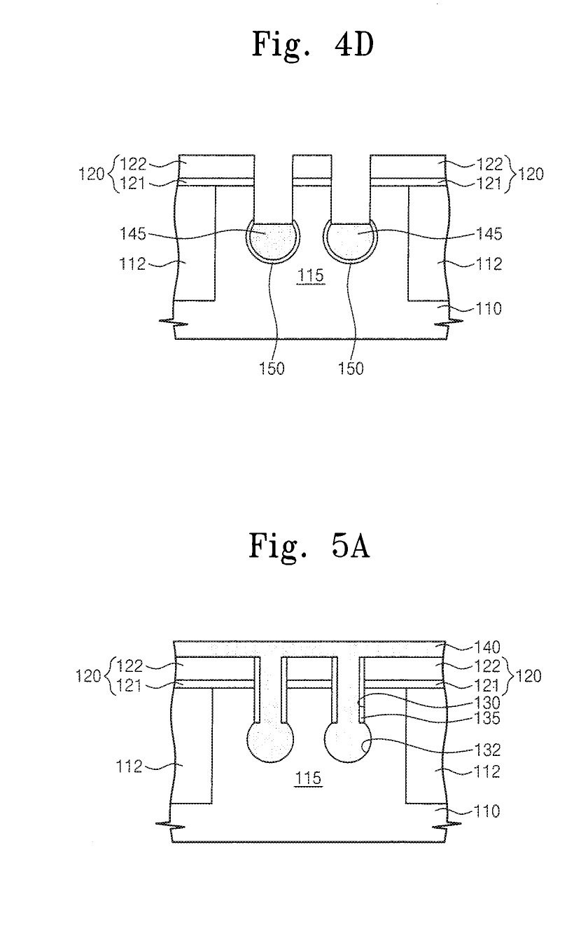

A method of forming a semiconductor device according to another embodiment of the present invention will now be described with reference to FIGS. 4A through 4D.

Initially, a trench 130 may be formed as exemplarily described with respect to FIG. 3A.

Referring to FIG. 4A, a spacer 135 is then formed on opposing sidewalls of the trench 130. The spacer 135 may be formed forming a mask layer (not shown) on a substrate 110 and, thereafter, subjecting the mask layer to an etchback process. The mask layer may include a material such as an oxide, a nitride, or the like or a combination thereof. Due to the etchback process, the substrate 110 may be exposed at a bottom surface of the trench 130.

Referring to FIG. 4B, an etch process is performed using the spacer 135 formed on the sidewalls of the trench 130 as an etch mask to etch the substrate 110 exposed at the bottom surface of the trench 130 and to form a recess region 133. The recess region 133 may have a substantially circular cross-section. The etch process may, for example, be an isotropic etch using an etch recipe having a high etch selectivity for etching a material of the substrate 110 (e.g., silicon) relative to a material of the spacer 135 (e.g., oxide, nitride, etc.). As a result of the isotropic etch process, a width of the recess region 132 may be larger than a width of the trench 130.

Referring to FIG. 4C, the spacer is removed, and a material pattern 145 containing impurity ions is formed in the recess region 132. In one embodiment, the material pattern 145 may be formed by forming a material layer containing impurity ions on the substrate 110, followed by etching the material layer. In one embodiment, the impurity ions contained the material layer (and, therefore, the material pattern 145) may include boron ions. In one embodiment, the material layer (and, therefore, the material pattern 145) may include a material such as borosilicate glass (BSG). In one embodiment, the material layer may be etched in an etchback process.

Referring to FIG. 4D, an annealing process is performed to form an impurity region 150 in portions of the substrate 110 that are adjacent to and contact the material pattern 145. The impurity region 150 may be formed by diffusing impurity ions (e.g., boron ions) from the material pattern 145 into the substrate 110 during the annealing process. The impurity ions may be substantially uniformly diffused by the annealing process, allowing the impurity region 150 to be substantially uniformly formed along the profile of the material pattern 145. As a result, the impurity region 150 may have, for example, a substantially circular cross-section and a substantially uniform doping profile.

Returning to FIG. 2, the material pattern 145 and the mask pattern 120 are removed using, for example, a wet etch process. An insulating layer and a conductive layer are then formed along the inner surfaces of the trench 130 and the recess region 132 and patterned to form a gate insulating layer 160 and a gate electrode 170, respectively. In one embodiment, the insulating layer may include an oxide formed using, for example, a thermal oxidation process. In one embodiment, the conductive layer may include polysilicon, metal, silicide, or the like or a combination thereof.

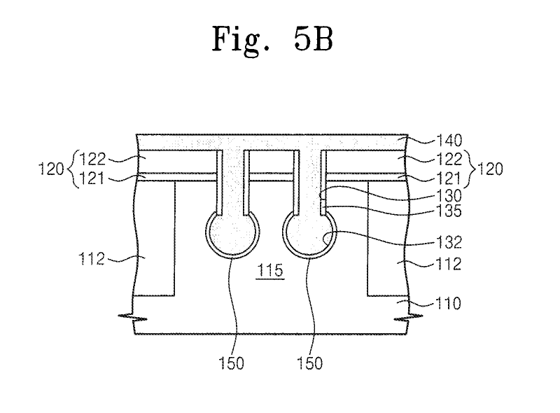

FIGS. 5A and 5B are cross-sectional views illustrating a method of forming a semiconductor device according to yet another embodiment of the present invention.

Initially, a trench 130, a spacer 135 and a recess region 132 may be formed as exemplarily described with respect to FIGS. 4A and 4B.

Referring to FIG. 5A, a material layer 140 is then formed on a substrate 110 to fill the recess region 132 and the trench 130. In one embodiment, the material layer 140 contains impurity ions such as boron ions. In one embodiment, the material layer 140 may include a material such as borosilicate glass (BSG). As exemplarily illustrated, the spacer 135 is interposed between the material layer 140 and the substrate 110 in the trench 130. However, the material layer 140 directly contacts the portion of the substrate 110 exposed at the recess region 132.

Referring to FIG. 5B, an annealing process is performed to form an impurity region 150 in portions of the substrate 110 that are adjacent to and contact the material layer 140. The impurity region 150 may be formed by diffusing impurity ions (e.g., boron ions) from the material layer 140 into the substrate 110 during the annealing process. Since the spacer 135 is formed on the sidewall of the trench 130, the spacer 135 acts as ion diffusion mask. As a result, impurity ions are not diffused into the sidewall of the trench 130 but are diffused into portions of the substrate 110 that directly contact the material layer 140 in the recess region 132. Accordingly, the impurity region 150 may be formed along the profile of the material layer 140 below the spacer 135. The impurity ions may be substantially uniformly diffused by the annealing process, allowing the impurity region 150 to be substantially uniformly formed along the profile of the material layer 140. As a result, the impurity region 150 may have, for example, a substantially circular cross-section and a substantially uniform doping profile.

Returning to FIG. 2, the material layer 140, the spacer 135 and the mask pattern 120 are removed using, for example, a wet etch process. An insulating layer and a conductive layer are then formed along the inner surfaces of the trench 130 and the recess region 132 and patterned to form a gate insulating layer 160 and a gate electrode 170, respectively. In one embodiment, the insulating layer may include an oxide formed using, for example, a thermal oxidation process. In one embodiment, the conductive layer may include polysilicon, metal, silicide, or the like or a combination thereof.

According to the embodiments exemplarily described above, an impurity region is substantially uniformly formed to be only below a trench (for a channel) where a gate electrode is disposed, by means of a thermal diffusion process. As a result, a threshold voltage of a recess channel array transistor may be effectively controlled to decrease leakage current and enhance operation characteristics, such as a refresh characteristic, of the recess channel array transistor.

Embodiments of the present invention may be practiced in many ways. A non-limiting description of some exemplary embodiments is provided in the following paragraphs.

One embodiment of the present invention may be generally characterized as a method of forming a semiconductor device that includes: defining an active region in a substrate; forming a trench in the active region; forming a material pattern containing impurity ions at a lower portion of the trench; diffusing the impurity ions to form an impurity region in the substrate, wherein the impurity region may contact the material pattern; removing the material pattern; forming an insulating pattern along an inner surface of the trench; and forming a conductive pattern in the trench.

According to the aforementioned method, the material pattern may be formed by: forming a spacer on the sidewall of the trench; and etching a bottom surface of the trench using the spacer as an etch mask to form a recess region.

According to the aforementioned method, the material pattern may be formed at the recess region.

In one embodiment, the impurity ions may be boron ions.

In one embodiment, the material pattern may be formed of borosilicate glass (BSG).

In one embodiment, the impurity ions may be diffused by performing an annealing process.

In one embodiment, the impurity region may be formed along the profile of the material pattern.

Another embodiment of the present invention may be generally characterized as a method of forming a semiconductor device that includes: defining an active region in a substrate; forming a trench in the active region; forming a spacer at a sidewall of the trench; etching a bottom surface of the trench using the spacer as an etch mask to form a recess region; forming a material layer containing impurity ions at the trench and the recess region; diffusing the impurity ions to form an impurity region at the substrate below the spacer, wherein the impurity region may contact the material layer; removing the material layer and the spacer; forming an insulating pattern along an inner surface of the trench; and forming a conductive pattern in the trench.

In one embodiment, the impurity ions may be boron ions.

In one embodiment, the material layer may be formed of borosilicate glass (BSG).

In one embodiment, the impurity ions may be diffused by performing an annealing process.

In one embodiment, the impurity region may be formed along the profile of the material layer.

Yet another embodiment of the present invention may be generally characterized as a semiconductor device that includes an active region defined in a substrate, wherein the active region has a trench extending below a surface of the substrate; an impurity region provided along a bottom surface and a lower sidewall of the trench, wherein an upper portion of the impurity region is spaced apart from the surface of the substrate and an upper portion of the trench; a gate insulating layer provided along an inner surface of the trench; and a gate electrode provided in the trench.

In one embodiment, the impurity region has a substantially uniform doping profile.

In one embodiment, the impurity region includes boron ions.

In one embodiment, the impurity region has substantially the same profile as a lower profile of the gate electrode.

In one embodiment, the semiconductor device may further include a recess region below the trench, wherein a width of the recess region may be greater than a width of the trench.

In one embodiment, the gate insulating layer may be provided along an inner surface of the recess region and the gate electrode may be provided in the recess region.

In one embodiment, the semiconductor device may further include source/drain regions disposed in the active region, wherein the source/drain regions and the gate electrode constitute a transistor.

Although embodiments of the present invention have been exemplarily described in connection with the accompanying drawings, the embodiments are not limited thereto. It will be apparent to those skilled in the art that various substitutions, modifications and changes may be made without departing from the scope and spirit of the invention.

What is claimed is:

1. A semiconductor device comprising:
an active region defined in a substrate, the active region having a trench extending below a surface of the substrate;
an impurity region provided along a bottom surface and a lower sidewall of the trench, wherein an upper portion of the impurity region is spaced apart from the surface of the substrate and an upper portion of the trench;
a gate insulating layer provided along an inner surface of the trench; and
a gate electrode provided in the trench.

2. The semiconductor device as set forth in claim 1, wherein the impurity region has a substantially uniform doping profile.

3. The semiconductor device as set forth in claim 1, wherein the impurity region includes boron ions.

4. The semiconductor device as set forth in claim 1, wherein the impurity region has substantially the same profile as a lower profile of the gate electrode.

5. The semiconductor device as set forth at claim 1, further comprising a recess region below the trench, wherein a width of the recess region is greater than a width of the trench.

6. The semiconductor device as set forth at claim 5, wherein the gate insulating layer is provided along an inner surface of the recess region and the gate electrode is provided in the recess region.

7. The semiconductor device as set forth at claim 1, further comprising source/drain regions disposed in the active region, wherein the source/drain regions and the gate electrode constitute a transistor.
